(19) United States
(12) Patent Application Publication
(10) Pub. No.: US 2025/0391737 A1
(43) Pub. Date: Dec. 25, 2025

(54) SEMICONDUCTOR DEVICE WITH EMBEDDED COOLING

(71) Applicant: INTERNATIONAL BUSINESS MACHINES CORPORATION, ARMONK, NY (US)

(72) Inventor: Mark D. Schultz, Ossining, NY (US)

(21) Appl. No.: 18/751,130

(22) Filed: Jun. 21, 2024

(51) Int. Cl. H01L 23/46; H01L 23/36; H01L 23/48; H01L 23/49

(52) U.S. Cl. CPC H01L 23/46; H01L 23/36; H01L 23/49; H01L 23/481

(57) ABSTRACT

An electrical device including a number of layers coupled with column interconnect structures, the number of layers further including at least one active layer with and at least one heat transfer die layer, the at least one active layer includes a back end of line (BEOL) layer and the at least one heat transfer die layer includes no or comparatively little BEOL layer relative to the BEOL layer of the at least one active layer. The at least one heat transfer die layer is designed to be in contact with a coolant.

### BACKGROUND

### Technical Field

The present disclosure generally relates to semiconductor devices, and more particularly to a structure and fabrication method for large scale integration and cooling of 3D stacked semiconductor electrical devices.

### Description of the Related Art

Traditionally, semiconductor devices were fabricated on a single silicon substrate, limiting the number of components that could be integrated into a single chip. However, the advent of stacked semiconductor technology has enabled the stacking of multiple layers of semiconductor devices vertically within a single package. This approach allows for increased device density, reduced interconnect lengths, and improved overall performance. Central to the realization of stacked semiconductor structures are through silicon vias (TSVs), which serve as vertical interconnects between different layers of the chip. The TSVs may be created by etching holes through the silicon substrate and filling them with conductive materials such as copper, providing electrical connections between the stacked layers while minimizing signal propagation delays and power consumption.

### SUMMARY

According to an embodiment, an electrical device includes a number of layers coupled with column interconnect structures. The layers include at least one active layer and at least one heat transfer die layer. The at least one heat transfer die layer is fabricated to be in contact with a coolant on one or both sides.

In one embodiment, the electrical device includes a cooling channel between two adjacent die layers and between the column interconnect structures.

In one embodiment, each of at least one the active layer includes a back end of line (BEOL) layer, and the through thermal resistance of each at least one active layer is more than 2 Cmm²/W. There is a reasonable line over which the through thermal resistance becomes an issue in extracting heat through it and simple structures will generally have less than this level of thermal resistance

In one embodiment, the through thermal resistance of each of the at least one heat transfer die layer is less than 2 Cmm²/W and thus support heat extraction.

According to another embodiment, a method for constructing an electrical device includes creating a first array of a plurality of column interconnect structures. At least one of the plurality of column interconnect structures includes at least one through silicon via (TSV). Further, the method includes coupling an active layer to one end of the first array of the plurality of column interconnect structures. The method further includes coupling a first heat transfer die layer to another end of the first array of plurality of column interconnect structures. Further, the method includes creating a second array of plurality of column interconnect structures. The method further includes coupling one end the second array of plurality of column interconnect structures to the active layer. Further, the method includes coupling a second heat transfer die layer to another end of the second array of plurality of column interconnect structures.

In one embodiment, the method includes creating a third array of a plurality of column interconnect structures. Further, the method includes coupling one end of the third array of plurality of column interconnect structures to the second heat transfer die layer.

In one embodiment, the method includes coupling a third heat transfer die layer to another end of the third array of plurality of column interconnect structures.

In one embodiment, the method includes coupling the active layer with at least one heat transfer die layer from both sides via the column interconnect structures.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 depicts a cross sectional view of a stack of layers of an electrical device in accordance with an illustrative embodiment.

FIG. 2 depicts a cross-sectional view of an electrical device illustrating a plurality of layers of column interconnect structures in accordance with an illustrative embodiment.

FIG. 3 depicts a cross-sectional view of an electrical device illustrating a column interconnect stack structure with etched semiconductor layers in accordance with an illustrative embodiment.

FIG. 4 depicts a cross-sectional view of an electrical device illustrating stacked columns of a plurality of column interconnect structures between two semiconductor layers of the electrical device in accordance with an illustrative embodiment.

FIG. 5 depicts a cross-sectional view of a single etched layer of the column interconnect structure in accordance with an illustrative embodiment.

FIG. 6A depicts a top-down view of the interface between a layer and a column interconnect structure, wherein metal pads at the interface have a substantially circular geometry in accordance with an illustrative embodiment.

FIG. 6B depicts a top-down view of another embodiment of the interface between a layer and a column interconnect structure, wherein metal pads at the interface have a multi-sided geometry in accordance with an illustrative embodiment.

FIG. 7 depicts a cross-sectional view of an electrical device illustrating a fabrication method in accordance with an illustrative embodiment.

FIG. 8 depicts a flowchart illustrating a routine for producing an electrical device with embedded cooling in accordance with an illustrative embodiment.

FIG. 9 illustrates a functional block diagram of a computer hardware platform in accordance with one embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below”, or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

The concepts herein relate to an electrical device comprising an embedded cooling feature. The electrical device may include stacked semiconductor dies or wafers generated by creating a semiconductor, e.g., silicon, “wall/pin only” spacer that can incorporate fine pitch through silicon via (TSV) structures. The wall/pin spacer may hereafter be referred to as a “column interconnect structure”. The column interconnect structure typically includes a through silicon via (TSV) structure that is formed using a sacrificial substrate. The through silicon via structure is formed to be in contact with the electrical communication features of active layers in a three-dimensional electrical device structure, i.e., an electrical device including stacked semiconductor layers and typically including cooling channels present there through.

The term “through silicon via (TSV) structure” is a vertical electrical connection (via) passing completely through a silicon layer, wafer, substrate or die. As used herein, the term “through silicon via structure” is not intended to only be limited to silicon containing structures, as any substrate through which a via extends is suitable for providing a TSVs, including any composition of the substrate. For example, in addition to silicon containing substrates, such as silicon (Si), silicon germanium (SiGe), silicon doped with carbon (Si:C), and silicon carbide (SiC), TSV structures may be formed through other semiconductor substrates, such as other type IV semiconductors, such as germanium (Ge), and compound semiconductors, such as type III-V semiconductors, e.g., gallium arsenide (GaAs) containing semiconductor substrates. It is also contemplated that the TSV structures that are the subject of the present disclosure as well as the “column interconnect structure” may also be formed through or with polymeric substrates, dielectric substrates, and glass substrates. In addition to providing for electrical coupling between separate layers, a column interconnect structure may also provide a structure that defines the spacing between adjacently stacked semiconductor layers in a manner that at least contributes to the geometry of cooling passages. It is also possible to construct column interconnect structures wholly of electrically conductive materials.

Before bonding, the “column interconnect structures” may comprise wall and/or pin structures with pads, interconnects, TSV structures, and/or features for isolating electrical interconnects from coolant, all attached to a handler structure. The spacer collection of structures, also referred to as the column interconnect structures, silicon channel structure(s) or silicon column structures, would be bonded to one layer in the stack, which may or may not have corresponding channel/pin structures etched to some depth.

After bonding, a handler structure would be released, leaving the collection of structures standing with a first end attached to a heat transfer die layer or active die layer. An active layer or heat transfer die layer may be attached to the opposite end of the structures. The process could be repeated many times to produce a 3D stacked electrical device with cooling channels for allowing coolant to circulate on both sides of a feature to be cooled.

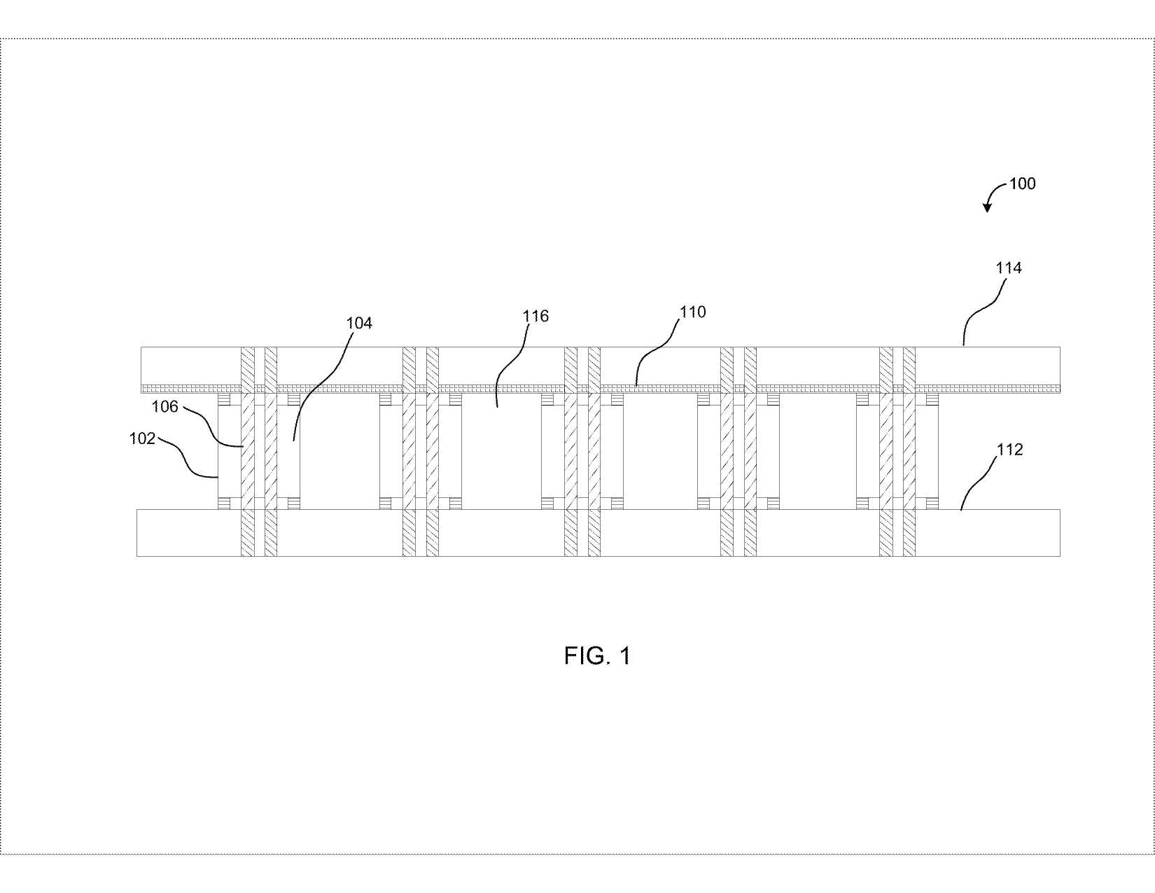

The active layer may include a back end of the line (BEOL) structure that possesses a high through thermal resistance relative to a layer that lacks the BEOL structure. The BEOL structure may be generated in a BEOL process during the latter stages of manufacturing of the electrical device wherein interconnects are formed to link transistors and other components generated during an initial front end of line (FEOL) process. The process to create the BEOL structure may include depositing metal layers separated by insulating materials and creating vias (vertical connections between layers) to form an intricate network of electrical pathways that ensure that signals can travel between different parts of the electrical device. Materials commonly used in BEOL processes include copper and aluminum for the metal layers and dielectric materials like silicon dioxide or other more advanced low-K dielectric materials to isolate these conductive pathways. An electrical path may be established from the BEOL structure to a source/drain contact. A carrier wafer may also be bonded on a surface of the BEOL layer to support the semiconductor device when performing various backside fabrication processes. The quality and precision of BEOL processes can dictate the performance and reliability of the electrical device. However, the BEOL structure also increases the overall through thermal resistance of the electrical device. As shown by the illustrative embodiments, the electrical device may include a heat transfer die layer and an active layer, two adjacent heat transfer die layers with an active layer disposed between the two heat transfer die layers or any number of other arrangements as discussed hereinafter. Though the BEOL structures can increase through thermal resistance, the arrangement of layers in the stack can decrease the overall through thermal resistance by virtue of increasing the cooling channels with the addition of heat transfer die layers between two adjacent active layers, the heat transfer die layers comprising little to no BEOL layers resulting in reduced through thermal resistance relative to typical active die layers. The methods and structures of the present disclosure are now discussed with more detail referring to FIGS. 1-9.

### Example Architecture

FIG. 1, illustrates a cross sectional view of a stack of semiconductor layers of an electrical device 100. A heat transfer die layer 112 is bonded to one end of a plurality of column interconnect structures 102 including a column-like geometry having semiconductor outer layers 104 and through silicon vias (TSVs) 106. Here “semiconductor outer layers 104” refers to layers comprising whatever substrate material is used as the base for forming the column interconnect structures, typically but not necessarily a semiconductor material. In referring to these outer layers, the terms “semiconductor” and “substrate material” may be used interchangeably. The heat transfer die layer 112 also comprises a substrate material, such as silicon. The other end of the plurality of column interconnect structures 102 is attached to an active layer 114. More specifically, the top and bottom of a column of the column interconnect structures 102 may be connected to an electrically conductive structure such as the BEOL or TSV’s of the active layer 114 and to the heat transfer die layer 112. In some cases, the heat transfer die layer may comprise comparatively limited low through thermal resistance (<2 Ccm2/W) BEOL and thus also include an electrically conductive structure in addition to the TSVs.

The electrically conductive structure that is electrically coupled with the column interconnect structures 102 is typically connected by a through silicon via (TSV) that extends through the layers, e.g., when the electrical signal or power carried by the column interconnect structures 102 is to extend through at least one of the heat transfer die layer 112 and the active layer 114. In an example, a first through silicon via (TSV) may be disposed in the heat transfer die layer 112 that is in contact, with the bottom surface of the column interconnect structures 102, and a second through silicon via (TSV) may be disposed in the active layer 114 that is in electrical communication with the top surface of the column interconnect structures 102.

The active layer 114 may include a plurality of semiconductor devices present thereon. Semiconductor devices may be absent from the heat transfer die layer. In some embodiments, as used herein, “semiconductor device” refers to a device utilizing an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentration in an extrinsic semiconductor determines the conductivity type of the semiconductor. The semiconductor devices may be switching devices, logic devices, and memory devices. Examples of switching devices and/or logic devices suitable for use with the present disclosure include p-n junction devices, bipolar junction transistors (BJT), field effect transistors, fin field effect transistors (FinFETS), Schottky barrier transistors, nanowire/nano-channel transistors and combinations thereof.

As used herein, a “field effect transistor” is a transistor in which output current, i.e., source-drain current, is controlled by the voltage applied to the gate. A field effect transistor has three terminals, i.e., gate, source and drain. A “FinFET” is a semiconductor device, in which the channel of the device is present in a fin structure. As used herein, a “fin structure” refers to a semiconductor material, which is employed as the body of a semiconductor device, in which the gate structure is positioned around the fin structure such that charge flows down the channel on the two sidewalls of the fin structure and optionally along the top surface of the fin structure. The heat transfer die layer 112 and/or the active layer 114 may also include passive electrical devices, such as capacitors and resistors. The plurality of column interconnect structures 102 include semiconductor outer layers 104 and through silicon vias (TSVs) 106. The column interconnect structures may be constructed of materials other than semiconductors, such as insulators or conductors. If insulators, the TSV’s would not require insulating material.

The TSV’s 106 provides for electrical coupling between at least two or more of the semiconductor layers (dies and/or wafers) and typically comprises a metal including, but not limited to W, Ni, Ti, Mo, Ta, Cu, Pt, Ag, Au, Ru, Ir, Rh, and Re, and alloys that include at least one of the aforementioned conductive elemental metals. In other embodiments, the TSV 106 may include a doped semiconductor material, such as a doped silicon containing material, e.g., doped polysilicon. The TSV 106 when viewed from a top-down perspective may be substantially circular or oblong or may be multi-sided. Typically, the TSV 106 may have a width ranging from 1000 nm to 20 microns. In other embodiments, the conductive material may have a width W1 ranging from 2 microns to 10 microns. As used herein, the term “electrical communication” means that a first structure or material, e.g., TSV 106, is electrically conductive to a second structure or material, e.g., the active layer 114 and/or devices within the active layer 114. “Electrically conductive” as used through the present disclosure can mean a material typically having a room temperature conductivity of greater than 10−8(-m)−1.

Turning back to FIG. 1, The active layer 114 may include a back end of the line (BEOL) layer 110 which can make the through thermal resistance of the active layer 114 to be at least 2 Cmm²/W. However, the heat transfer die layers 112 do not include a BEOL layer 110 or may include a limited BEOL layer 110 that, results in effectively low through thermal resistance of a maximum of 2 Cmm²/W. In an embodiment, the structure discussed herein reduces the through thermal resistance of the heat transfer die layer 112 by around 40% with an associated reduction in temperature.

In an embodiment, the assembly of the plurality of column interconnect structures 102 and the heat transfer die layer 112 and the active layer 114 creates cooling channel 116 for coolant flow, thereby allowing coolant to come into contact with the layers and the column interconnect structures 102. In some embodiments, cooling channel 116 may have a width W1 ranging from 100 microns to 400 microns. In other embodiments, each cooling channel 116 may have a width W2 ranging from 150 microns to 450 microns. In different embodiments, the width W1 may be at least 100 microns, 125 microns, 150 microns, 175 microns, 200 microns, 225 microns, 250 microns, 275 microns, 300 microns, 325 microns, 350 microns, 375 microns, 400 microns, 425 microns, 450 microns or 475 microns, or any range there between (e.g., 125 microns to 200 microns, or 175 microns to 225 microns). In some embodiments, each cooling channel 116 may have a height H1 ranging from 100 microns to 300 microns. In other embodiments, each cooling channel 116 may have a height H1 ranging from 125 microns to 175 microns. In different embodiments, the height H1 may be at least 100 microns, 110 microns, 120 microns, 130 microns, 140 microns, 150 microns, 160 microns, 170 microns, 180 microns, 190 microns, 200 microns, 210 microns, 220 microns, 230 microns, 240 microns, 250 microns, 260 microns, 270 microns, 280 microns, 290 microns or 300 microns, or any range there between (e.g., 130 microns to 160 microns). These dimensions may be appropriate for two phase embedded cooling.

The plurality of column interconnect structures 102 may be spaced to provide cooling channel 116 having a substantially similar width or may be spaced to provide cooling channel 116 having different widths within the same level of layers. For example, in some embodiments, e.g., when the cooling channel is to have substantially the same width, the pitch, i.e., center to center distance between adjacent column interconnect structures may range from 200 microns to 300 microns.

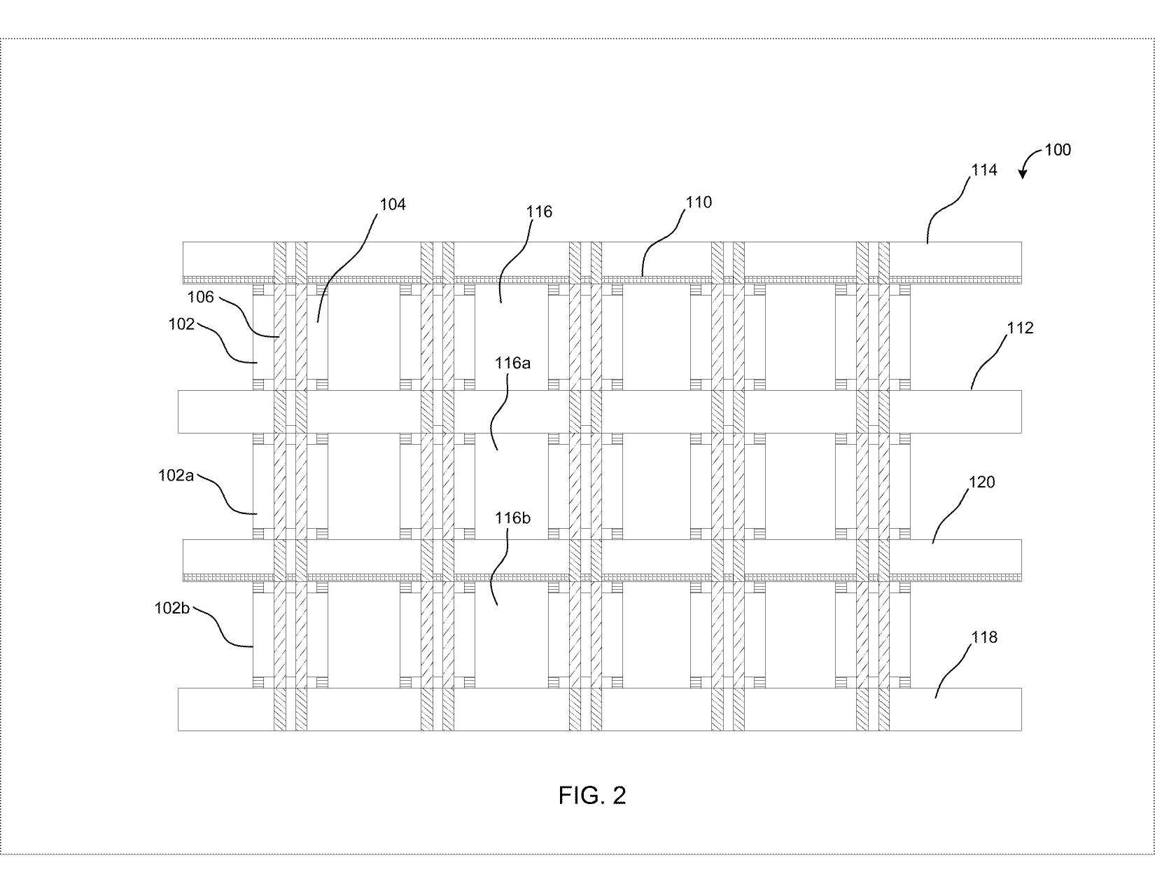

Turing now to FIG. 2, a simplified cross-section view of a column interconnect structure 102 of an electrical device 100 with a plurality of semiconductor layers is shown. The structure that is depicted in FIG. 2 may be referred to as having three spacer levels or two active levels and two heat transfer die levels. The additional layers 118 and 120 are similar to the heat transfer die layer 112 and the active layer 114 respectively that have been described above with reference to FIG. 1. For example, similar to the heat transfer die layer 112 and the active layer 114, the additional layers 118, 120 may each include a TSV structure, which can bring electrical signal through each of the layers 118, 120 and/or be in electrical communication with devices that are present on or within the layers 118, 120. Therefore, the above description of the heat transfer die layer 112 and the active layer 114 is suitable for the additional layers 118, 120 including the description for the composition and the types of devices, e.g., semiconductor, memory, and passive electrical devices, that are present within the layers.

In the multi-layer structure of FIG. 2, a coolant may flow through the cooling channels 116, 116a, 116b on both the top and bottom surfaces of interior layers 112, 120. The cooling channels 116, 116a, 116b comprise a geometry defined by the sidewall surfaces of the column interconnect structures 102, 102a, 102b, and the upper and lower surface of the layers 112, 114, 118, 120. Each of the cooling channel 116, 116a, 116b depicted in FIG. 2 may have the height H1 and width W1 of the cooling channel 116 that are described in FIG. 1. Similar to the embodiments described above with reference to FIG. 1, the multi-layered structure depicted in FIG. 2 may include any number of cooling channels.

To increase the effective cooling by the cooling channels, it is noted that the active layers 114, 120 are placed alternatively in the structure, and the heat transfer die layer 112 is placed between two adjacent active layers 114, 120 to decrease the total through thermal resistance of the stacked electrical device and increase the heat transfer surface area from which the heat generated by an active layer is removed. For example, in some embodiments, there may be more than one heat transfer die layer disposed between two active layers 114 and 120 to decrease the through thermal resistance and increase the effective cooling of the stacked electrical device.

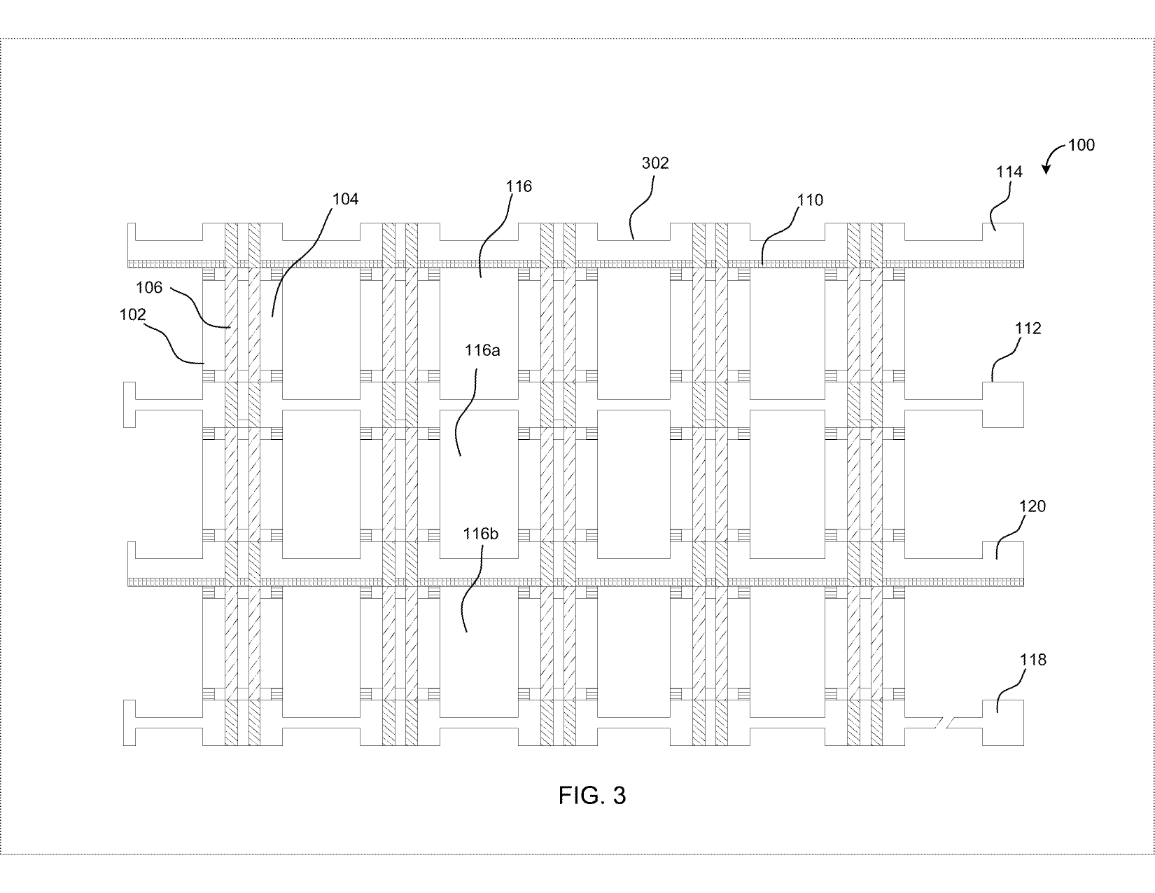

Turning now to FIG. 3, a cross-sectional view of a column interconnect stack structure comprising etched channels is shown. In an embodiment, the silicon of at least one of the active layers 114, 120 is etched to form trenches 302. The multi-layer electrical device depicted in FIG. 3 is similar to the multilayer electrical device that is depicted in FIG. 2, with the exception that the upper side of the active layers 114, 120, and both sides of the heat transfer die layers 112, 118 have been etched to form the trenches 302 in the portions of the layers between the column interconnect structures 102. Note that the trenches may be long narrow structures or may be more of a mesh-like structure if the column interconnect structures are of pin rather than wall form. Therefore, the description from FIG. 2 is suitable for the structure depicted in FIG. 1 of the elements having the same reference numbers in FIG. 3. When assembled, the trenches 302 increase the height of the cooling channels 116, 116a, 116b to allow a higher volume of coolant such as a dielectric fluid may be passed through the channels to cool the active layers 114, 120. For example, the depth of the trenches 302 may range from 5 microns to 75 microns. In another example, the depth of the trenches 302 may range from 10 microns to 25 microns. These depths may fit into either 50 or 100 micron thick layers.

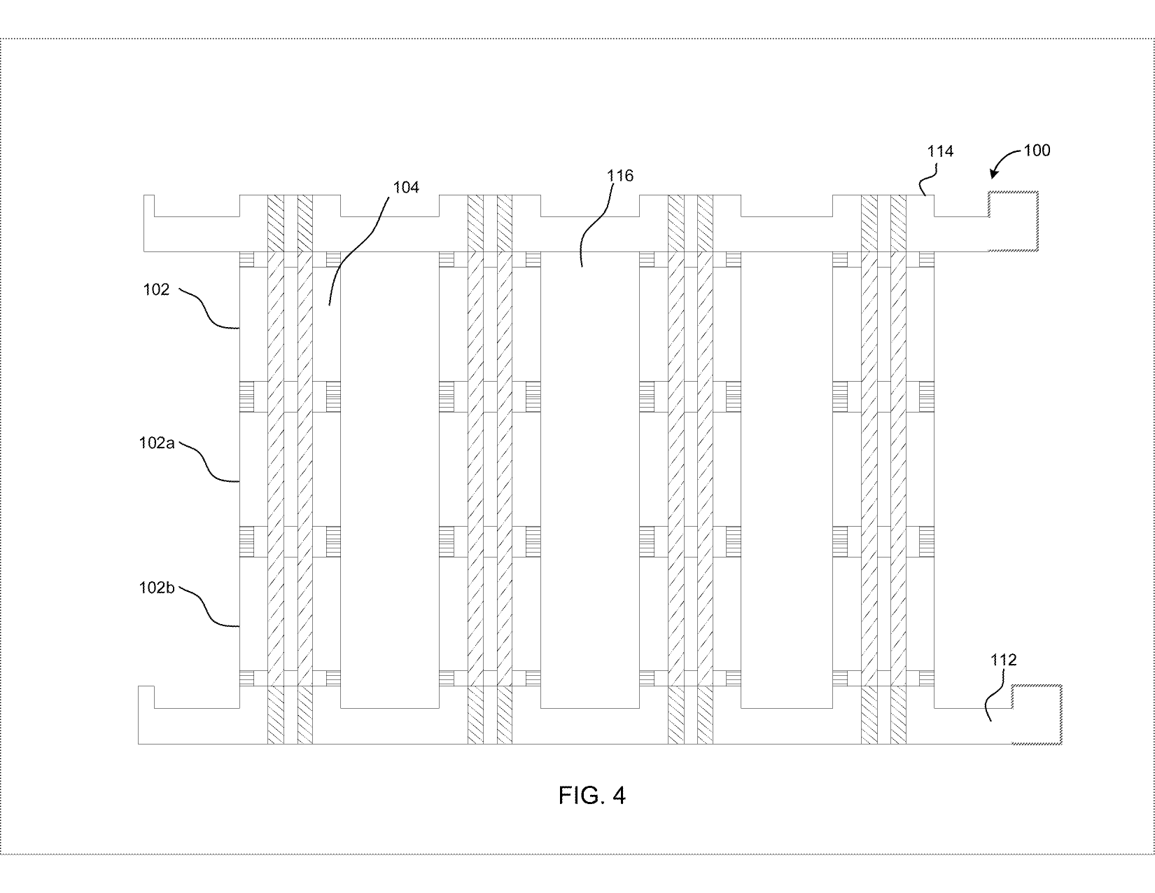

Turing now to FIG. 4, a multi-layered device structure, in which columns of a plurality of column interconnect structures 102, 102a, 102b are positioned between adjacently stacked active layer 114 and the heat transfer die layer 112 is shown. The adjacently stacked active layer 114 and the heat transfer die layer 112 can be considered as the same layers described above with reference to FIGS. 1-3.

By stacking a plurality of column interconnect structures 102, 102a, 102b between adjacently stacked at least one the active layer 114 and at least one the heat transfer die layer 112, the height of the cooling channel 116 may be increased. For example, in the embodiment depicted in FIG. 4, when each column of a plurality of column interconnect structures 102, 102a, 102b includes three column interconnect structures each having a height of, for example, 100 microns, the height of each cooling channel 116 may be, for example, 300 microns. Although FIG. 4 depicts three column interconnect structures 102, 102a, 102b, the present disclosure is not limited to only this embodiment, as any number of column interconnect structures 102, 102a, 102b may be present in a column separating adjacently stacked layers from one another. For example, a column of column interconnect structures may include 2, 3, 4, 5, 6, 7, 8, 9, 10, 15 or 20 column structures.

Each of the column interconnect structures 102, 102a, 102b may be bonded to the adjacent column interconnect structures 102, 102a, 102b in the stacked column. For example, a TSV 106 of each of the column interconnect structures 102, 102a, 102b in the stacked column may be bonded to the adjacent TSVof the adjacent column interconnect structures 102, 102a, 102b through a conductive bonded interface. For example, when the adjacent column interconnect structures 102, 102a, 102b are bonded to one another using methods employing solder bumps an electrically conductive interface between adjacent TSVs 1068 may be provided by the solder. The solder bump can provide an electrically conductive pad, e.g., metal pad, for adjoining ends of the TSVs 106 of each of the column interconnect structures 102, 102a, 102b. For simplicity, the BEOL layer is not illustrated.

It is noted that the columns of the plurality of column interconnect structures 102, 102a, 102b that are depicted in FIG. 4 may be incorporated into the embodiments depicted in FIGS. 1-3.

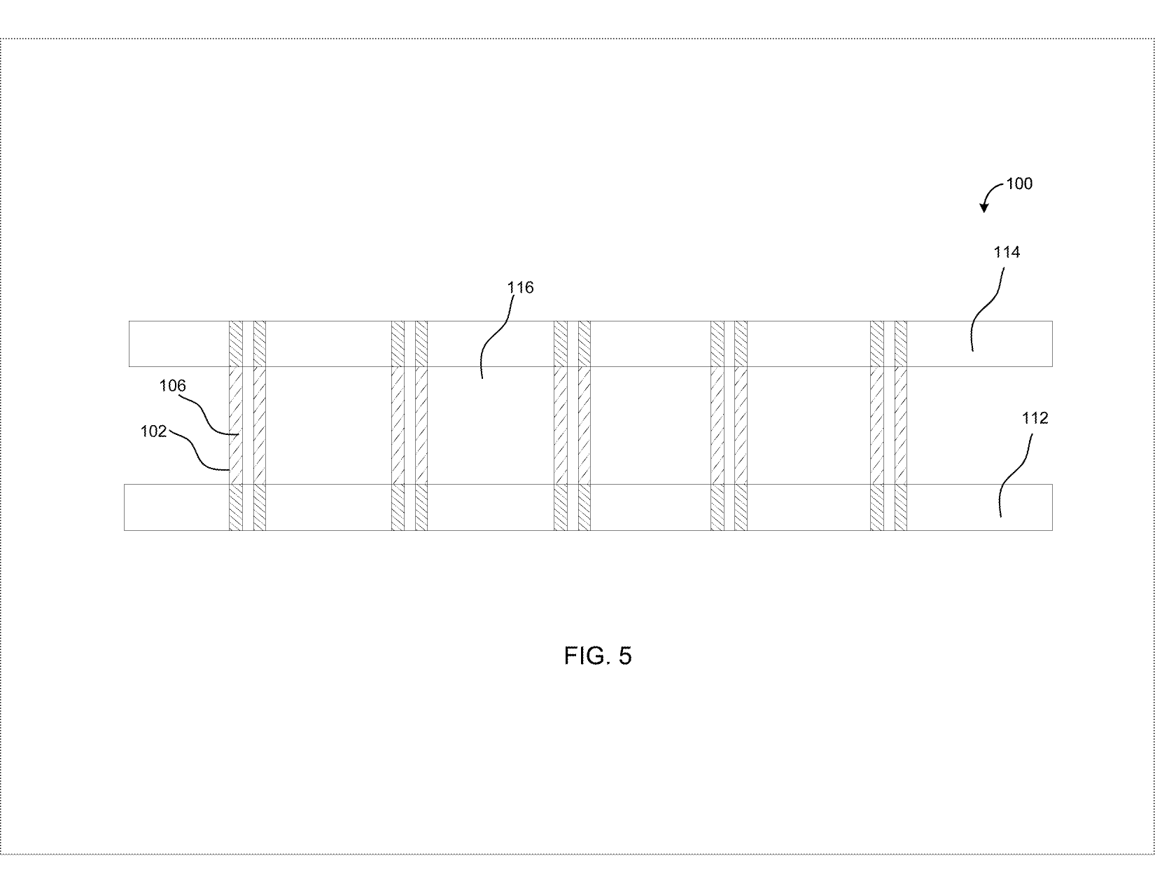

Turing now to FIG. 5, a cross-sectional view of a single layer of the column interconnect structure is shown as a comprising conductors, i.e., the TSVs 106 wherein the entirety of the sacrificial substrate material surrounding the TSV structure has been removed or the conductors were created with a method not requiring a sacrificial substrate. The TSVs 106 are separate structure from the active layer 114 and the heat transfer die layer 112 but are bonded to the active layer 114 and the heat transfer die layer 112 and provide electrical communication to or through at least the layers. The TSVs 106 also provide spacing between adjacently stacked layers, and in combination with the upper and lower sides of the active layer 114 and the heat transfer die layer 112, provide a cooling channel 116 for cooling the active layer 114, and devices present therein. For simplicity, the BEOL layer is not illustrated here. The cooling channel 116 depicted in FIG. 5 is typically used with a dielectric coolant and allows superior cooling of the interconnect structures, as well as the devices in the active layer 114 and the heat transfer die layer 112. It is noted that multiple column interconnect structures 102 may be employed in a column of stacked structures similar to the embodiment described above with reference to FIG. 4.

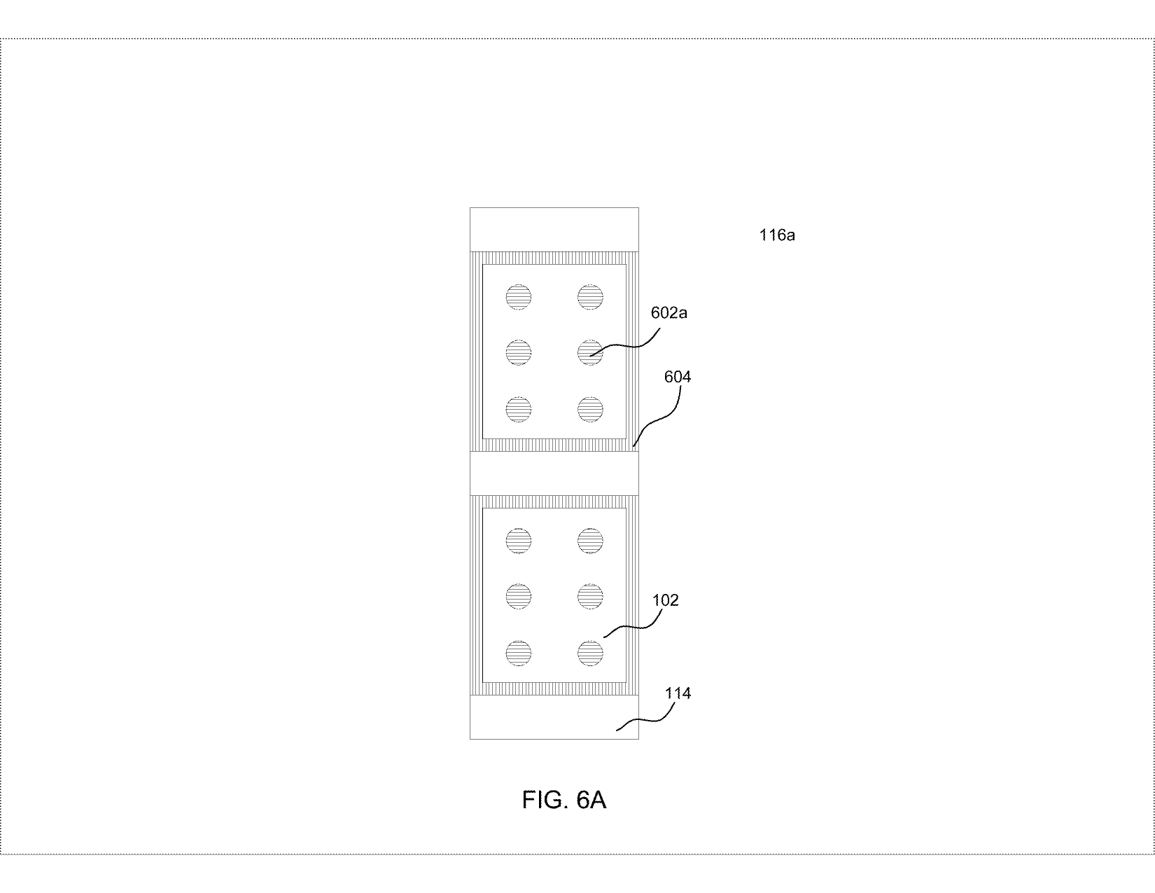

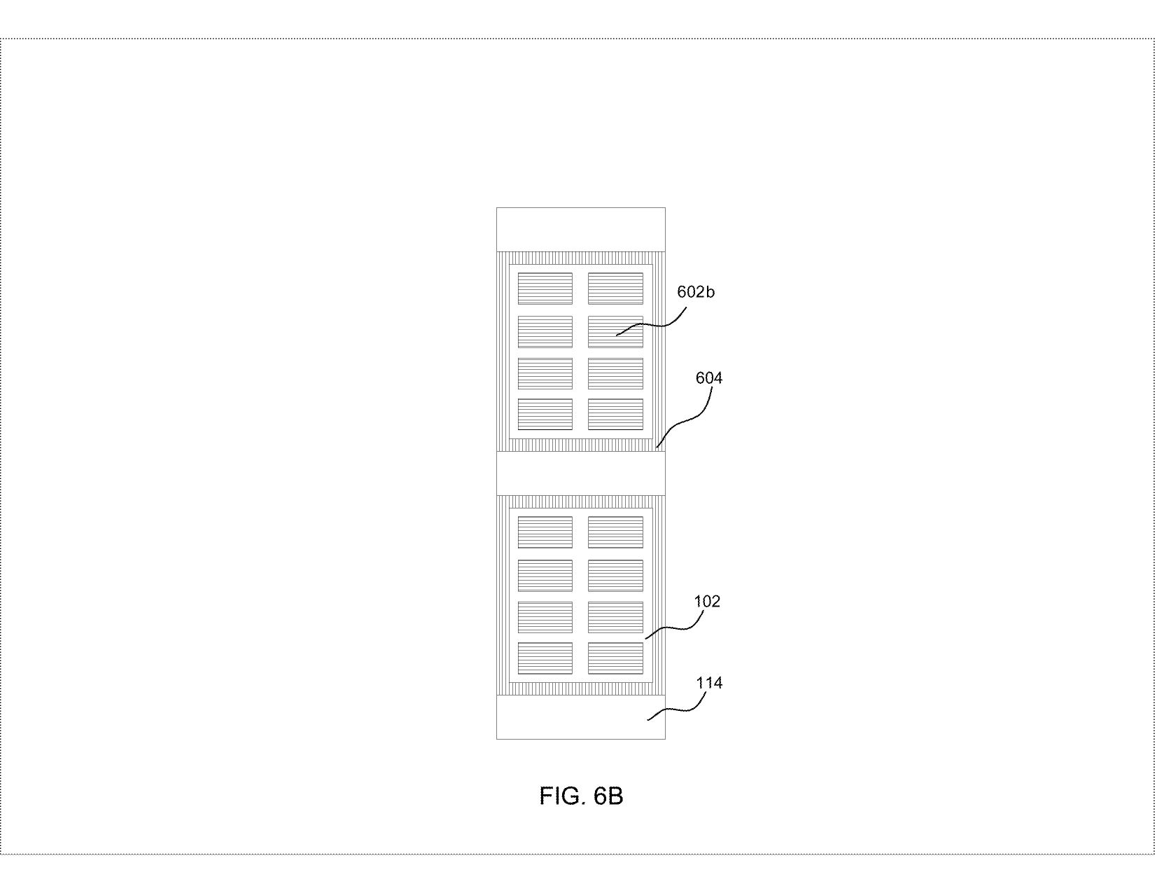

Turning now to FIG. 6A, a top-down view of the interface between a layer and a column interconnect structure 102 is shown. The area between the column interconnect structures 102 and atop the active layer 114 is the cooling channel. The cooling channels are formed to direct coolant through the structure. A plurality of metal pads 602a and a coolant seal 604 connect the column interconnect structures 102 to the heat transfer die layer 112 (not shown in FIG. 6A). The metal pads 602a provide for electrical communication from the TSV 106 (not shown in FIG. 6A) of the plurality of column interconnect structures 102 to the TSV structure in the heat transfer die layer 112.

The coolant seal 604 isolates the metal interconnects of the column interconnect structures 102 when non-dielectric coolant is used. In one embodiment, the coolant seal 604 may be both affixed to the wall/pin section, i.e., column interconnect structures 102, and attached to the layer, i.e., active layer 114, using the same materials and by essentially the same process as the electrical (solder) interconnect process. The seal material could alternatively be added to either the wall/pin or active die by a separate deposition or patterning process of a separate material such as a polymer. This polymer could be cured either as part of the solder attach (reflow) process or with a separate cure step.

FIG. 6A depicts one embodiment of the interface between the column interconnect structure 102 and the active layer 114 when the metal pads 602a have a substantially circular cross section. FIG. 6B depicts another embodiment of the interface between the column interconnect structure 102 and the active layer 114. In the embodiment depicted in FIG. 6B, the rectangular, or potentially hexagonal geometry of the metal pads 602b are provided for a high density and improved thermal behavior.

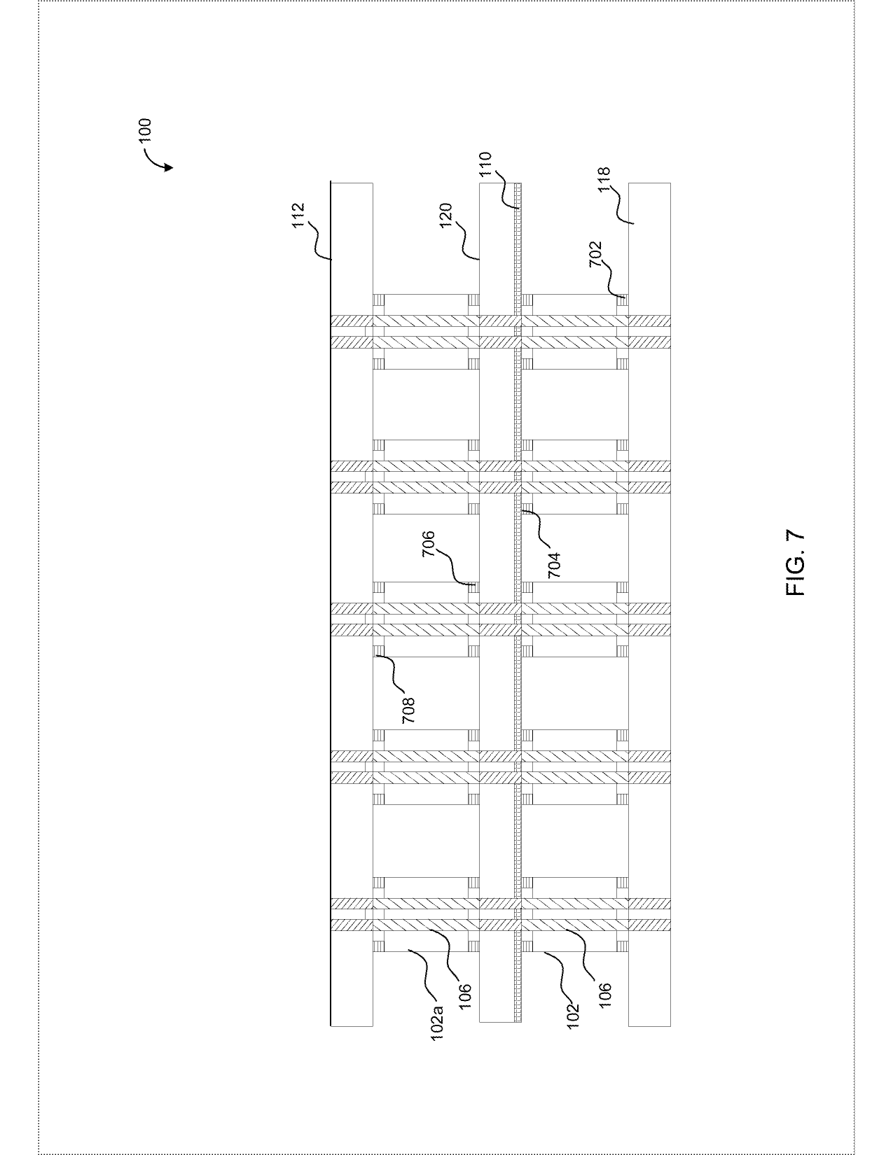

Turning now to FIG. 7, a cross-sectional view of the electrical device 100 is shown to illustrate a method of producing the electrical device 100. The electrical device 100 may be created by stacking at least one active layer 120 and at least one heat transfer die layer 112, 118 coupled together by arrays of the plurality of column interconnect structures 102, 102a. In an exemplary embodiment, the at least one active layer 120 is made up of substrate material comprising a plurality of semiconductor devices. The semiconductor devices are incorporated in the substrate material to create the active layer. The substrate material is a die or wafer layer made up of at least one of silicon, silicon germanium, silicon doped with carbon (Si:C), germanium (Ge), silicon germanium doped with carbon (SiGe:C), silicon carbide, type III-V compound semiconductor materials and a combination thereof. It should be noted that the semiconductor devices are incorporated in the substrate material of the active layer and coupled to a Back End of Line (BEOL) process, effectively creating a thin BEOL layer 110 on at least one side of the active layer 120. The BEOL layer 110 causes the through thermal resistance of each of the at least one active layer 120 to be at least 2 Cmm²/W.

Further, each of the at least one heat transfer die layers 112, 118 is also constructed of a substrate material. The substrate material is a layer which may comprise at least one of silicon, silicon germanium, silicon doped with carbon (Si:C), germanium (Ge), silicon germanium doped with carbon (SiGe:C), silicon carbide, type III-V compound semiconductor materials and a combination thereof. Further, the plurality of column interconnect structures 102, 102a are arranged in arrays of plurality of levels.

Further, an exemplary method of creating the electrical device 100 is explained. In an embodiment, a heat transfer die layer 118 is coupled to one end 702 of the plurality of column interconnect structures 102. Further, the other end 704 of the plurality of column interconnect structures 102 is coupled to the active layer 120 through a BEOL layer 110 side or from a opposite side. The coupling of the active layer 120 and the heat transfer die layer 118 is performed, for example, by soldering the ends of each of the plurality of column interconnect structures 102 to the surfaces of the active layer 120 and the heat transfer die layer 118. The column interconnect structures may be temporarily bonded to glass handlers using an adhesive material, the glass handlers aiding in the control or handling of the column interconnect structures for attachment for the active layers 120 and heat transfer die layers 118. This arrangement of the active layer 120, the heat die transfer layer 118 and the plurality of column interconnect structures 102 create hollow spaces that may act as cooling channels 116. The dielectric coolant may be passed through the cooling channel 116.

One end 706 of the plurality of column interconnect structures 102a can be coupled to the active layer 120. It should be noted that the plurality of column interconnect structures 102a and the plurality of column interconnect structures 102 are coupled to opposite sides of the active layer 120. Further, the heat transfer die layer 112 is coupled to another end 708 of the plurality of column interconnect structures 102a. Further, the TSV 106 of each of the plurality of column interconnect structures 102, 102a is passed through the active layer 120 and the heat transfer die layers 112, 118 to electrically connect a number of layers as desired.

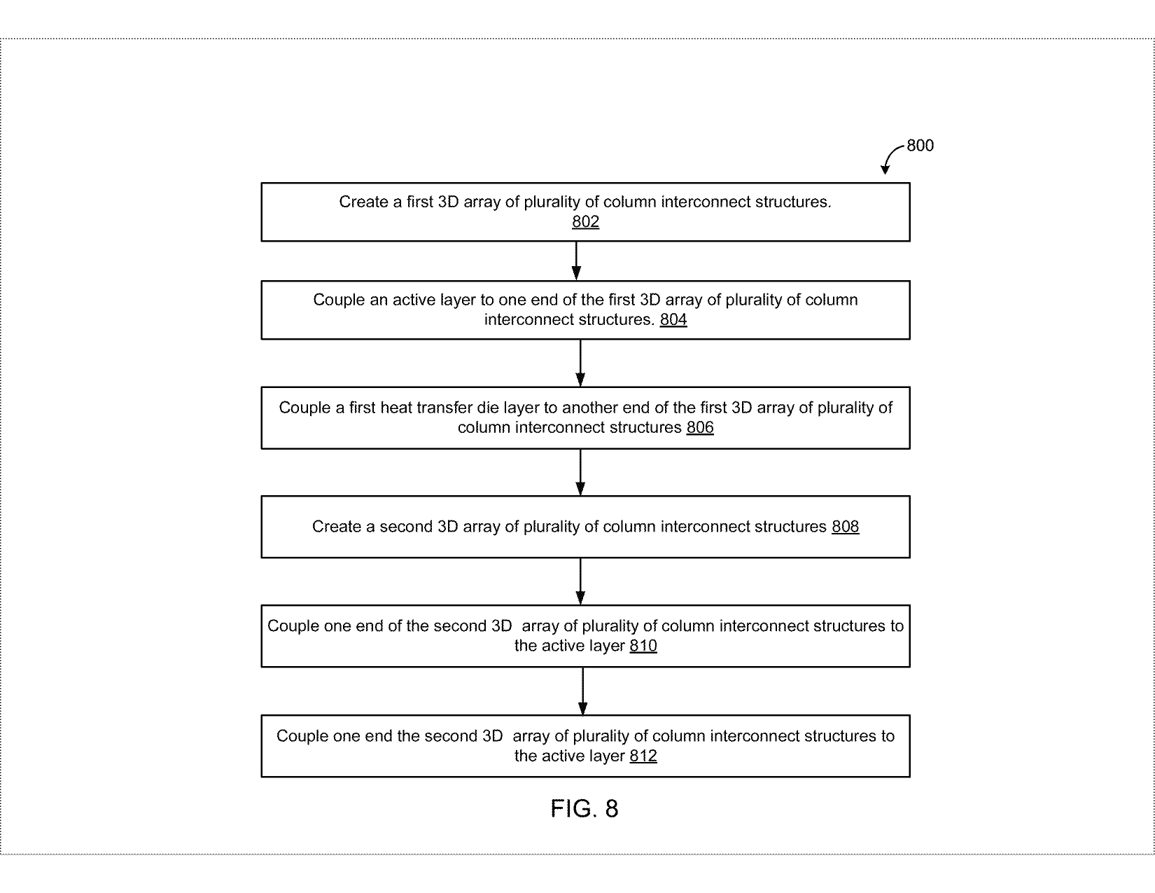

Turning now to FIG. 8, a flowchart of method of construction of the stacked electrical device with embedded cooling is shown. At block 802, a first array of plurality of column interconnect structures is created. At least one of the plurality of column interconnect structures includes at least one through silicon via (TSV). The column interconnect structures typically comprise silicon. The column interconnect structures also accommodate at least one conductive material for carrying electrical signals within the electrical device.

At block 804, an active layer is coupled to one end of the first array of plurality of column interconnect structures. The active layer is coupled by a soldering or bumping process to the ends of the first array of the plurality of the column interconnect structures. At block 806, a first heat transfer die layer is coupled to another end of the first array of plurality of column interconnect structures. Another end of the first array of plurality of column interconnect structures is the opposite end to which the active layer is coupled. At block 808, a second array of plurality of column interconnect structures is created. The second array of plurality of column interconnect structures is created by spacing each column interconnect structure in an even or uneven distance. At block 810, one end the second array of plurality of column interconnect structures is coupled to the active layer. The second array of plurality of column interconnect structures is coupled to the opposite surface of the active layer in a way that second array of plurality of column interconnect structures is positioned on top of the stacked electrical device. At block 812, a second heat transfer die layer is coupled to another end of the second array of plurality of column interconnect structures. Thus, a plurality of cooling channels is created between two adjacent layers and the plurality of interconnect structures, and a coolant is flowed in the plurality of cooling channels. Further, the blocks 802 to 812 may be iterated to create an electrical device comprising a desired number of heat transfer die layers and active layers.

In an embodiment, the first heat transfer die layer, the second heat transfer die layer and the active layer is made of a substrate which may comprise a material selected from a group consisting of silicon, silicon germanium, silicon doped with carbon (Si:C), germanium (Ge), silicon germanium doped with carbon (SiGe:C), silicon carbide, type III-V compound semiconductor materials and a combination thereof. It should be noted that the total through thermal resistance of the active layer is maintained more than 2 Cmm²/W, and the total through thermal resistance of the first heat transfer die layer and the second heat transfer die layer is maintained less than 2 Cmm²/W. Further, the active layer is etched on one side to increase surface area of the active layer, and the first heat transfer die layer and the second heat transfer die layer are etched on both sides to increase the surface area.

While the manufacture of a 3D stacked chip or electrical device is described for the purposes of discussion, it will be understood that other configurations, as well as those having multiple heat transfer die layers between two active layers are supported by the teachings herein.

In one aspect, the method and structures as described above may be used in the fabrication of 3D stacked integrated chips or electrical devices. The resulting electrical devices can be distributed by the fabricator in raw wafer form (that is, as a single wafer that has multiple unpackaged chips), as a bare die, or in a packaged form. In the latter case, the device may be mounted in a single chip package (such as a plastic carrier, with leads that are affixed to a motherboard or other higher-level carrier) or in a multichip package (such as a ceramic carrier that has either or both surface interconnections or buried interconnections). In any case, the device can then be integrated with other devices, discrete circuit elements, and/or other signal processing devices as part of either (a) an intermediate product, such as a motherboard, or (b) an end product. The end product can be any product that includes electrical device, ranging from low-end applications, such as toys, to advanced computer products having a display, a keyboard or other input device, and a central processor.

### Example Computer Platform

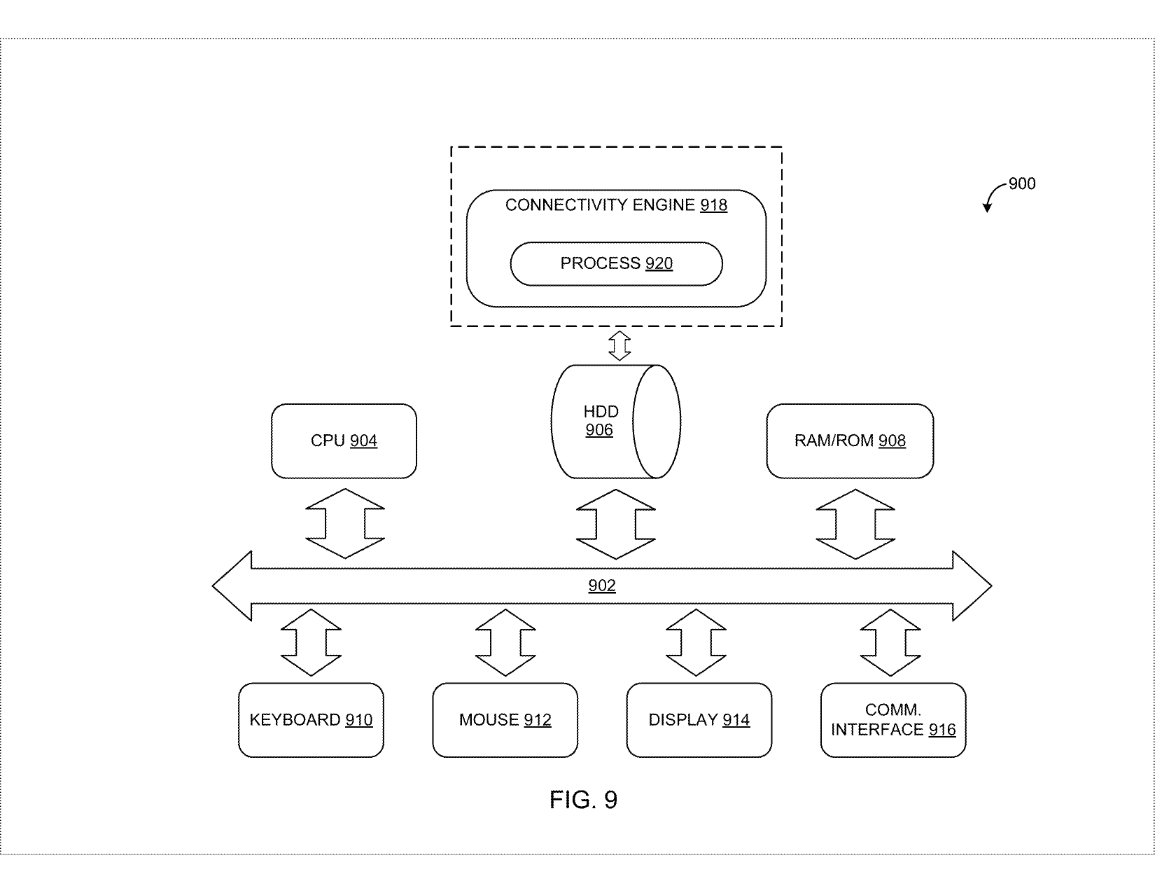

As discussed above, functions relate to stacked chip device with embedded cooling. FIG. 9 is a functional block diagram illustration of a computer hardware platform that can be used to control various aspects of a suitable computing platform 900 in which the various embodiments of the features discussed herein can be implemented. While a single computing device is illustrated for simplicity, it will be understood that a combination of additional computing devices, program modules, and/or combination of hardware and software can be used as well. The computer platform 900 may include a central processing unit (CPU) 904, a hard disk drive (HDD) 906, random access memory (RAM) and/or read only memory (ROM) 908, a keyboard 910, a mouse 912, a display 914, and a communication interface 916, which are connected to a system bus 902.

In one embodiment, the HDD 906 has capabilities that include storing a program that can execute various processes, such as the connectivity engine 918, in a manner described herein. The connectivity engine 918 may have various modules configured to perform different functions. For example, there may be a process module 920 configured to control the different manufacturing processes discussed herein and others.

### Conclusion

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. An electrical device, comprising:
a plurality of layers coupled with column interconnect structures, the plurality of layers comprising:
at least one active layer having a back end of line (BEOL) layer; and
at least one heat transfer die layer having no BEOL layer or a BEOL layer having a through thermal resistance of less than 2 Cmm²/W, wherein the at least one heat transfer die layer is in contact with a coolant.

2. The electrical device of claim 1, further comprising a cooling channel between each of two adjacent layers.

3. The electrical device of claim 2, wherein the coolant is a dielectric coolant.

4. The electrical device of claim 1, wherein:
at least one of the column interconnect structures comprises at least one through silicon via (TSV); and
at least one TSV comprises at least one metal layer.

5. The electrical device of claim 1, wherein each of the plurality of layers comprise a substrate including a material that is at least one of silicon, silicon germanium, silicon doped with carbon (Si:C), germanium (Ge), silicon germanium doped with carbon (SiGe:C), silicon carbide, type III-V compound semiconductor materials, or a combination thereof.

6. The electrical device of claim 1, wherein a total through thermal resistance of the at least one active layer is more than 2 Cmm²/W.

7. The electrical device of claim 6, wherein each of the at least one active layer is in contact with the coolant from one side.

8. The electrical device of claim 1, wherein a total through thermal resistance of the at least one heat transfer die layer is less than 2 Cmm²/W.

9. The electrical device of claim 1, wherein each of the at least one active layer is coupled with at least one heat transfer die layer on both sides of the at least one layer via the column interconnect structures.

10. The electrical device of claim 1, wherein:
the at least one active layer is etched on one side to increase a surface area of the at least one active layer; and
the at least one heat transfer die layer is etched on both sides and configured to increase the surface area of the at least one heat transfer die layer.

11. The electrical device of claim 1, wherein the column interconnect structures comprise a metal without a substrate.

12. A method for constructing an electrical device, the method comprising:
creating a first array of a plurality of column interconnect structures, wherein each of the plurality of column interconnect structures includes at least one through silicon via (TSV);
coupling an active layer to one end of the first array of plurality of column interconnect structures;
coupling a first heat transfer die layer to another end of the first array of plurality of column interconnect structures;
creating a second array of plurality of column interconnect structures;
coupling one end the second array of plurality of column interconnect structures to an active layer; and
coupling a second heat transfer die layer to another end of the second array of plurality of column interconnect structures.

13. The method of claim 12, further comprising:
creating a plurality of cooling channels between two adjacent layers and the plurality of interconnect structures; and
flowing a coolant in the plurality of cooling channels.

14. The method of claim 12, wherein the active layer, the first heat transfer die, and the second heat transfer die each comprise a substrate including one or more materials selected from silicon, silicon germanium, silicon doped with carbon (Si:C), germanium (Ge), silicon germanium doped with carbon (SiGe:C), silicon carbide, type III-V compound semiconductor.

15. The method of claim 12, further comprising maintaining a total through thermal resistance of the active layer to be more than 2 Cmm²/W.

16. The method of claim 12, further comprising maintaining a total through thermal resistance of the each of the first heat transfer die layer and the second heat transfer die layer less than 2 Cmm²/W.

17. The method of claim 12, further comprising:
creating a third array of a plurality of column interconnect structures; and
coupling one end of the third array of the plurality of column interconnect structures to the second heat transfer die layer.

18. The method of claim 17, further comprising coupling a third heat transfer die layer to another end of the third array of plurality of column interconnect structures.

19. The method of claim 12, further comprising coupling the active layer with at least one heat transfer die layer from both sides via the column interconnect structures.

20. The method of claim 12, further comprising etching the active layer on one side to increase a surface area of the active layer.
